(19) United States
(12) Patent Application Publication
(10) Pub. No.: US 2026/0101660 A1
(43) Pub. Date: Apr. 9, 2026

(54) DISPLAY DEVICE AND MANUFACTURING METHOD OF DISPLAY DEVICE

(71) Applicant: Magnolia White Corporation, Tokyo (JP)

(72) Inventors: Sho YANAGISAWA, Tokyo (JP); Yozo NAKAYASU, Tokyo (JP); Naoya IWAHASHI, Tokyo (JP)

(73) Assignee: Magnolia White Corporation, Tokyo (JP)

(21) Appl. No.: 19/352,526

(22) Filed: Oct. 8, 2025

(30) Foreign Application Priority Data
Oct. 8, 2024 (JP) 2024-176442

(51) Int. Cl. H10K 59/80; H10K 59/12; H10K 59/122; H10K 59/35

(52) U.S. Cl. CPC H10K 59/871; H10K 59/1201; H10K 59/122; H10K 59/353; H10K 59/80515; H10K 59/8052

(57) ABSTRACT

According to one embodiment, a display device includes, a first display element, a second display element, a third display element, a partition surrounding each of the first display element, the second display element, and the third display element, a first sealing layer covering the first display element, a second sealing layer covering the second display element, and a third sealing layer covering the third display element. A distance between the second sealing layer and the third sealing layer is greater than a distance between the first sealing layer and the third sealing layer. A reflective layer is not provided between the partition and the first sealing layer, between the partition and the second sealing layer, and the partition and the third sealing layer.

### CROSS-REFERENCE TO RELATED APPLICATIONS

This application is based upon and claims the benefit of priority from Japanese Patent Application No. 2024-176442, filed Oct. 8, 2024, the entire contents of which are incorporated herein by reference.

### FIELD

Embodiments described herein relate generally to a display device and a manufacturing method of a display device.

### BACKGROUND

Recently, display devices with organic light-emitting diodes (OLED) applied thereto as display elements have been put into practical use. This type of display devices demand a technique for improving the display quality.

### BRIEF DESCRIPTION OF THE DRAWINGS

FIG. 1 is a view showing a configuration example of a display device DSP.

FIG. 2 is a view showing an example of the layout of subpixels SP1, SP2, and SP3 which constitute one pixel PX.

FIG. 3 is a view for describing a configuration example of the pixel PX.

FIG. 4 is a view showing a configuration example of the layout of sealing layers SE11, SE12, and SE13.

FIG. 5 is a schematic cross-sectional view of the display device DSP along the A-B line of FIG. 4.

FIG. 6A is a view for describing a manufacturing method of the display device DSP.

FIG. 6B is a view for describing the manufacturing method of the display device DSP.

FIG. 6C is a view for describing the manufacturing method of the display device DSP.

FIG. 6D is a view for describing the manufacturing method of the display device DSP.

FIG. 6E is a view for describing the manufacturing method of the display device DSP.

FIG. 6F is a view for describing the manufacturing method of the display device DSP.

FIG. 6G is a view for describing the manufacturing method of the display device DSP.

FIG. 6H is a view for describing the manufacturing method of the display device DSP.

FIG. 6I is a view for describing the manufacturing method of the display device DSP.

FIG. 6J is a view for describing the manufacturing method of the display device DSP.

FIG. 6K is a view for describing the manufacturing method of the display device DSP.

FIG. 6L is a view for describing the manufacturing method of the display device DSP.

FIG. 7A is a view for describing a manufacturing method of a comparative example.

FIG. 7B is a view for describing the manufacturing method of the comparative example.

FIG. 7C is a view for describing the manufacturing method of the comparative example.

FIG. 8 is a view showing another configuration example of the layout of the sealing layers SE11, SE12, and SE13.

FIG. 9 is a view showing another configuration example of the layout of the sealing layers SE11, SE12, and SE13.

FIG. 10 is a view showing another configuration example of the layout of the sealing layers SE11, SE12, and SE13.

FIG. 11 is a view showing another configuration example of the layout of the sealing layers SE11, SE12, and SE13.

FIG. 12 is a view showing another configuration example of the layout of the sealing layers SE11, SE12, and SE13.

FIG. 13 is a view showing another configuration example of the layout of the sealing layers SE11, SE12, and SE13.

FIG. 14 is a view showing another configuration example of the layout of the sealing layers SE11, SE12, and SE13.

### DETAILED DESCRIPTION

An object of the embodiment is to provide a display device capable of improving the display quality and a manufacturing method of the display device.

In general, according to one embodiment, a display device includes a substrate, an inorganic insulating layer provided above the substrate, a first display element configured to display a first color, a second display element configured to display a second color different from the first color, a third display element configured to display a third color different from the first color and the second color, a partition provided on the inorganic insulating layer, having conductivity, surrounding each of the first display element, the second display element, and the third display element, and formed in an overhang shape, a first sealing layer covering the first display element and extending above the partition, a second sealing layer covering the second display element and extending above the partition, and a third sealing layer covering the third display element and extending above the partition. A distance between the second sealing layer and the third sealing layer is greater than a distance between the first sealing layer and the third sealing layer. A reflective layer is not provided between the partition and the first sealing layer, between the partition and the second sealing layer, and the partition and the third sealing layer.

According to another embodiment, a display device includes a substrate, an inorganic insulating layer provided above the substrate, a partition provided on the inorganic insulating layer, having conductivity, and formed in an overhang shape, and a plurality of pixels provided in a matrix in a first direction and a second direction. Each of the plurality of pixels comprises a first display element configured to display a first color and surrounded by the partition, a second display element configured to display a second color different from the first color and surrounded by the partition, a third display element configured to display a third color different from the first color and the second color and surrounded by the partition, a first sealing layer covering the first display element and extending above the partition, a second sealing layer covering the second display element and extending above the partition, and a third sealing layer covering the third display element and extending above the partition. The third sealing layer is located between two of the first sealing layers in the first direction. A distance between one of the first sealing layers and the third sealing layer in the first direction is greater than a distance between the other first sealing layer and the third sealing layer in the first direction. A reflective layer is not provided between the partition and the first sealing layer, between the partition and the second sealing layer, and the partition and the third sealing layer.

According to another embodiment, a display device manufacturing method includes providing a processing substrate above a substrate, the processing substrate including a first lower electrode, a second lower electrode, a third lower electrode, and a partition having an overhang shape and surrounding each of the first lower electrode, the second lower electrode, and the third lower electrode, forming a first stacked film on the first lower electrode, the first stacked film including a first organic layer, a first upper electrode, and a first cap layer, forming a first sealing layer on the first stacked film, forming a second stacked film on the second lower electrode, the second stacked film including a second organic layer, a second upper electrode, and a second cap layer, forming a second sealing layer on the second stacked film, forming a second sealing layer on the second stacked film, forming a third stacked film on the first sealing layer, the second sealing layer, the partition, and the third lower electrode, the third stacked film including a third organic layer, a third upper electrode, and a third cap layer, forming a third sealing layer on the third stacked film, forming a resist patterned into a predetermined shape on the third sealing layer, and patterning the third sealing layer and the third stacked film using the resist as a mask. The resist is formed such that a distance from the resist to an edge portion of the second sealing layer is greater than a distance from the resist to an edge portion of the first sealing layer.

The embodiment can provide a display device capable of improving the display quality and a manufacturing method of the display device.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the figures, an X-axis, a Y-axis, and a Z-axis orthogonal to each other are described to facilitate understanding as needed. A direction parallel to the X-axis is referred to as a first direction X. A direction parallel to the Y-axis is referred to as a second direction Y. A direction parallel to the Z-axis is referred to as a third direction Z. A plan view is defined as appearance when various types of elements are viewed parallel to the third direction Z. When terms indicating the positional relationships of two or more structural elements, such as “on”, “above” “between” and “face”, are used, the target structural elements may be directly in contact with each other or may be spaced apart from each other as a gap or another structural element is interposed between them. The positive direction of the Z-axis is referred to as an upward direction or a direction to an upper side.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone, and a wearable terminal.

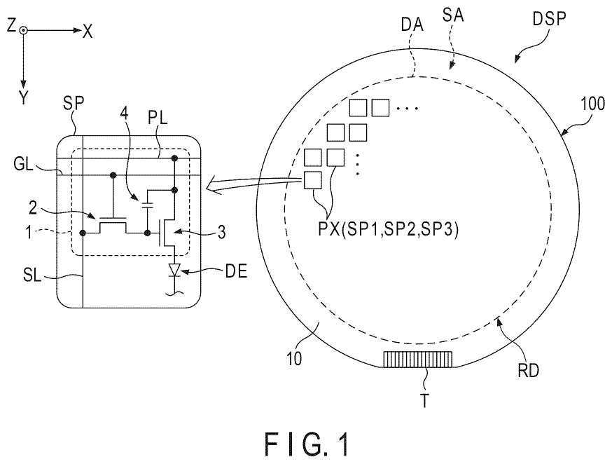

FIG. 1 is a view showing a configuration example of a display device DSP.

The display device DSP comprises a display panel 100. The display panel 100 has a display area DA for displaying images and a surrounding area SA around the display area DA on an insulating substrate 10. The substrate 10 may be either a glass substrate or a resinous substrate having flexibility.

The outer edge of at least a portion of the display area DA has a round portion RD. In the illustrated example, the display area DA has a circular shape in plan view. The shape of the display area DA in plan view is not limited to the illustrated example. For example, the outer edge of the display area DA may be constituted by the round portion RD and a straight portion.

The display area DA comprises a plurality of pixels PX arranged in a matrix in the first direction X and the second direction Y. Each pixel PX includes a plurality of subpixels SP that display different colors. For example, each pixel PX includes a subpixel SP1, which displays the first color, a subpixel SP2, which displays the second color, and a subpixel SP3, which displays the third color. The first color, the second color, and the third color are different colors. Each pixel PX may include a subpixel SP, which displays another color such as white in addition to the subpixels SP1, SP2, and SP3 or instead of one of the subpixels SP1, SP2, and SP3.

The round portion RD in the display area DA is a shape in a macroscopic scale. In a microscopic scale, this shape is formed by providing a plurality of pixels PX in a stair step layout.

The subpixel SP comprises a pixel circuit 1 and a display element DE driven by the pixel circuit 1. The pixel circuit 1 comprises a pixel switch 2, a drive transistor 3, and a capacitor 4. The pixel switch 2 and the drive transistor 3 are, for example, switching elements constituted by thin-film transistors.

A gate electrode of the pixel switch 2 is connected to a scanning line GL. One of a source electrode or a drain electrode of the pixel switch 2 is connected to a signal line SL. The other is connected to a gate electrode of the drive transistor 3 and the capacitor 4. In the drive transistor 3, one of a source electrode and a drain electrode is connected to a power line PL and the capacitor 4. The other is connected to the display element DE. In the illustrated example, the scanning line GL and the power line PL extend in the first direction X and the signal line SL extends in the second direction Y.

The configuration of the pixel circuit 1 is not limited to the illustrated example. For example, the pixel circuit 1 may comprise more thin-film transistors and capacitors.

For example, the display element DE is an organic light emitting diode (OLED) as a light emitting element and thus may be called an organic EL element.

The display device DSP further comprises a terminal portion T provided in the surrounding area SA. The terminal portion T comprises a plurality of terminals. For example, the terminal portion T is electrically connected to an IC chip or a flexible printed circuit board for driving the display elements DE.

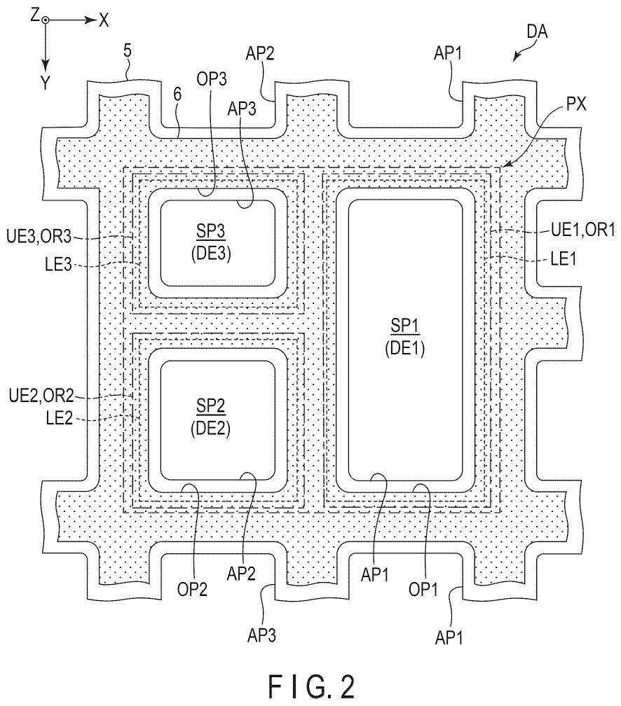

FIG. 2 is a view showing an example of the layout of the subpixels SP1, SP2, and SP3 which constitute one pixel PX.

In the illustrated example, the subpixels SP2 and SP3 are arranged in the second direction Y. Further, the subpixels SP1 and SP2 are arranged in the first direction X, and the subpixel SP1 and SP3 are arranged in the first direction X.

When the subpixels SP1, SP2, and SP3 are arranged in this layout, in the display area DA, a column in which the subpixels SP2 and SP3 are alternately arranged in the second direction Y and a column in which the plurality of subpixels SP1 are arranged in the second direction Y are formed. These columns are alternately arranged in the first direction X. The layout of the subpixels SP1, SP2, and SP3 is not limited to the illustrated example.

An inorganic insulating layer 5 and a partition 6 are provided in the display area DA. The inorganic insulating layer 5 has apertures AP1, AP2, and AP3 in the respective subpixels SP1, SP2, and SP3. The inorganic insulating layer 5 having these apertures AP1, AP2, and AP3 may be called a rib.

The partition 6 overlaps the inorganic insulating layer 5 in plan view. The partition 6 is formed in a grating shape surrounding the apertures AP1, AP2, and AP3. In other words, the partition 6 has respective apertures OP1, OP2, and OP3 in the subpixels SP1, SP2, and SP3 in the same manner as the inorganic insulating layer 5. The aperture OP1 overlaps the aperture AP1. The aperture OP2 overlaps the aperture AP2. The aperture OP3 overlaps the aperture AP3. The partition 6 is conductive and is electrically connected to a terminal with common voltage at the terminal portion T shown in FIG. 1.

The subpixels SP1, SP2, and SP3 comprise respective display elements DE1, DE2, and DE3 as the display elements DE.

The display element DE1 of the subpixel SP1 comprises a lower electrode LE1, an upper electrode UE1, and an organic layer OR1, which overlap the aperture AP1. The peripheral portion of the lower electrode LE1 is covered with the inorganic insulating layer 5. The lower electrode LE1, the organic layer OR1, and the upper electrode UE1, which constitute the display element DE1 are surrounded by the partition 6 in plan view. The peripheral portion of each of the organic layer OR1 and the upper electrode UE1 overlaps the inorganic insulating layer 5 in plan view.

The display element DE2 of the subpixel SP2 comprises a lower electrode LE2, an upper electrode UE2, and an organic layer OR2, which overlap the aperture AP2. The peripheral portion of the lower electrode LE2 is covered with the inorganic insulating layer 5. The lower electrode LE2, the organic layer OR2, and the upper electrode UE2, which constitute the display element DE2 are surrounded by the partition 6 in plan view. The peripheral portion of each of the organic layer OR2 and the upper electrode UE2 overlaps the inorganic insulating layer 5 in plan view.

The display element DE3 of the subpixel SP3 comprises a lower electrode LE3, an upper electrode UE3, and an organic layer OR3, which overlap the aperture AP3. The peripheral portion of the lower electrode LE3 is covered with the inorganic insulating layer 5. The lower electrode LE3, the organic layer OR3, and the upper electrode UE3, which constitute the display element DE3 are surrounded by the partition 6 in plan view. The peripheral portion of each of the organic layer OR3 and the upper electrode UE3 overlaps the inorganic insulating layer 5 in plan view.

In the illustrated example, the outlines of the lower electrodes LE1, LE2, and LE3 are indicated by broken lines, and the outlines of the organic layers OR1, OR2, and OR3 and the upper electrodes UE1, UE2, and UE3 are indicated by short dashed lines. The outlines of the respective lower electrode, organic layer, and upper electrode shown in the figure may not reflect the exact shapes.

For example, the lower electrodes LE1, LE2, and LE3 correspond to the anodes of the display elements. The upper electrodes UE1, UE2, and UE3 correspond to the cathodes of the display elements or a common electrode and contact the partition 6.

The lower electrode LE1 is electrically connected to the pixel circuit 1 (refer to FIG. 1) of the subpixel SP1. The lower electrode LE2 is electrically connected to the pixel circuit 1 of the subpixel SP2. The lower electrode LE3 is electrically connected to the pixel circuit 1 of the subpixel SP3.

In the illustrated example, the planar size of the aperture AP1, the planar size of the aperture AP2, and the planar size of the aperture AP3 differ from each other. The planar size of the aperture AP1 is greater than the aperture AP2. The planar size of the aperture AP2 is greater than the aperture AP3. The magnitude relationship of the planar sizes of the apertures AP1, AP2, and AP3 is not limited to the illustrated example.

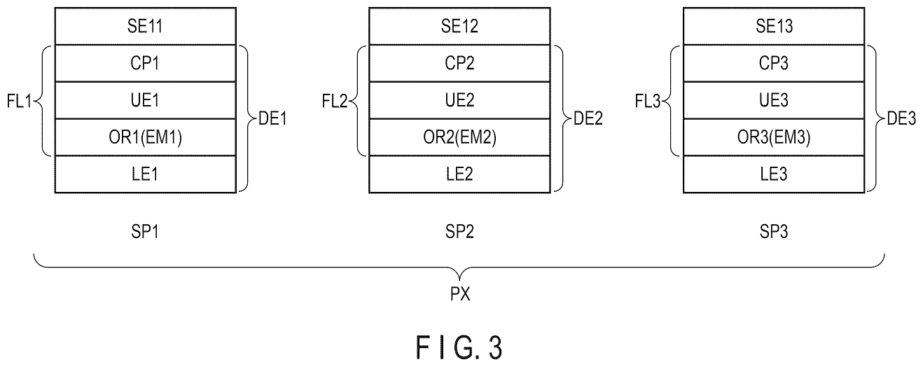

FIG. 3 is a view for describing a configuration example of the pixel PX.

The display element DE1 comprises the lower electrode LE1, the organic layer OR1, the upper electrode UE1, and a cap layer CP1 in the subpixel SP1. The organic layer OR1 including a light emitting layer EM1 is provided between the lower electrode LE1 and the upper electrode UE1. The cap layer CP1 is provided on the upper electrode UE1. The sealing layer SE11 is provided on the cap layer CP1 and covers the display element DE1.

The display element DE2 comprises the lower electrode LE2, the organic layer OR2, the upper electrode UE2, and a cap layer CP2 in the subpixel SP2. The organic layer OR2 including a light emitting layer EM2 is provided between the lower electrode LE2 and the upper electrode UE2. The cap layer CP2 is provided on the upper electrode UE2. The sealing layer SE12 is provided on the cap layer CP2 and covers the display element DE2.

The display element DE3 comprises the lower electrode LE3, the organic layer OR3, the upper electrode UE3, and a cap layer CP3 in the subpixel SP3. The organic layer OR3 including a light emitting layer EM3 is provided between the lower electrode LE3 and the upper electrode UE3. The cap layer CP3 is provided on the upper electrode UE3. The sealing layer SE13 is provided on the cap layer CP3 and covers the display element DE3.

In the following explanation, a multilayer body including the organic layer OR1, the upper electrode UE1, and the cap layer CP1 may be called a stacked film FL1. A multilayer body including the organic layer OR2, the upper electrode UE2, and the cap layer CP2 may be called a stacked film FL2. A multilayer body including the organic layer OR3, the upper electrode UE3, and the cap layer CP3 may be called a stacked film FL3.

The light emitting layers EM1, EM2, and EM3 are formed of materials different from each other. For example, the light emitting layer EM1 is formed of a material that emits light in a blue wavelength range. The light emitting layer EM2 is formed of a material that emits light in a green wavelength range. The light emitting layer EM3 is formed of a material that emits light in a red wavelength range. That is, the display element DE1 is configured to display blue color as the first color, the display element DE2 is configured to display green color as the second color, and the display element DE3 is configured to display red color as the third color.

The light emitting layer EM1 may be formed of a material that emits light in a green wavelength. The light emitting layer EM2 may be formed of a material that emits light in a blue wavelength. That is, the display element DE1 may be configured to display green color as the first color, the display element DE2 may be configured to display blue color as the second color.

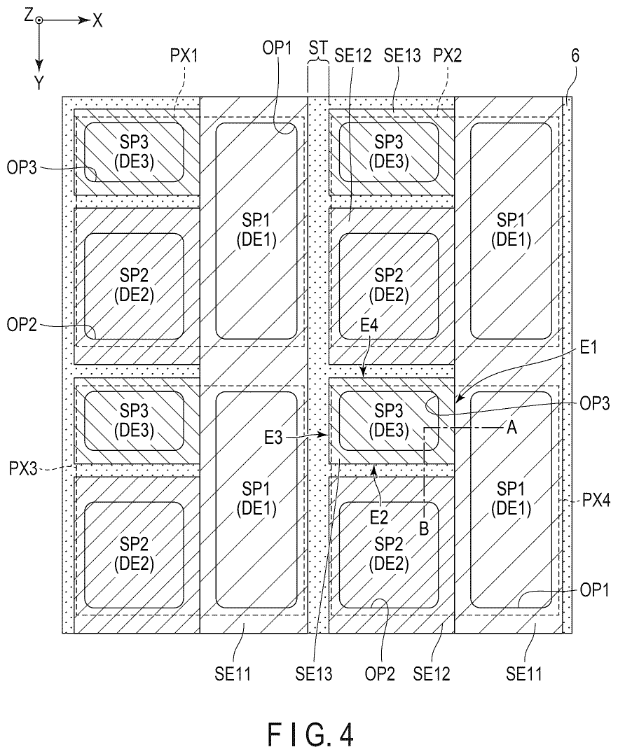

FIG. 4 is a view showing a configuration example of the layout of the sealing layers SE11, SE12, and SE13.

The figure shows four pixels: pixels PX1, PX2, PX3, and PX4 in the display area DA shown in FIG. 1. Each of the pixels PX1, PX2, PX3, and PX4 comprises the subpixels SP1, SP2, and SP3 arranged in the layout shown in FIG. 2.

The pixels PX1 and PX2 are arranged in the first direction X. The pixels PX3 and PX4 are arranged in the first direction X. The pixels PX1 and PX3 are arranged in the second direction Y. The pixels PX2 and PX4 are arranged in the second direction Y.

In each of the pixels PX1, PX2, PX3, and PX4, the display element DE1 of the subpixel SP1 is covered with the sealing layer SE11, the display element DE2 of the subpixel SP2 is covered with the sealing layer SE12, and the display element DE3 of the subpixel SP3 is covered with the sealing layer SE13.

The sealing layer SE11 is provided in the aperture OP1 overlapping the display element DE1 in the partition 6 and extends onto the partition 6. The sealing layer SE12 is provided in the aperture OP2 overlapping the display element DE2 in the partition 6 and extends onto the partition 6. The sealing layer SE13 is provided in the aperture OP3 overlapping the display element DE3 in the partition 6 and extends onto the partition 6. The edge portion of each of the sealing layers SE11, SE12, and SE13 is entirely located on the partition 6.

A slit-shaped area ST is formed between the pixels PX1 and PX2 and between the pixels PX3 and PX4. None of the sealing layers SE11, SE12, and SE13 are provided in the area ST. The partition 6 is exposed from the sealing layers SE11, SE12, and SE13 in the area ST.

The following describes on the pixel PX4.

The sealing layers SE11 and SE13 are arranged in the first direction X. The sealing layers SE12 and SE13 are arranged in the second direction Y. In the illustrated example, the distance between the sealing layers SE12 and SE13 in the second direction Y is greater than the distance between the sealing layers SE11 and SE13 in the first direction X.

In plan view, the sealing layer SE13 is formed in a rectangular shape extending in the first direction X and has a pair of edge portions E1 and E3 extending in the second direction Y and a pair of edge portions E2 and E4 extending in the first direction X. The edge portion E1 is close to the sealing layer SE11 and may contact the sealing layer SE11. The edge portion E2 is spaced apart from the sealing layer SE12. That is, the slit-shaped areas ST respectively extend between the edge portion E2 and the sealing layer SE12. When the edge portion E1 is spaced apart from the sealing layer SE11, the slit-shaped areas ST respectively extend between the edge portion E1 and the sealing layer SE11 as well.

The following describes on the pixels PX3 and PX4 adjacent to each other in the first direction X.

The sealing layer SE13 of the pixel PX4 is located between the sealing layer SE11 of the pixel PX3 and the sealing layer SE11 of the pixel PX4 in the first direction X. The edge portion E3 of the sealing layer SE13 is spaced apart from the sealing layer SE11 of the pixel PX3. That is, the slit-shaped areas ST respectively extend between the edge portion E3 and the sealing layer SE11. As illustrated, the distance between the sealing layers SE11 of the pixel PX3 and the sealing layer SE13 of the pixel PX4 in the first direction X is greater than the distance between the sealing layer SE11 of the pixel PX4 and the sealing layer SE13 of the pixel PX4 in the first direction X.

The following describes on the pixels PX2 and PX4 adjacent to each other in the second direction Y.

The sealing layer SE13 of the pixel PX4 is located between the sealing layer SE12 of the pixel PX2 and the sealing layer SE12 of the pixel PX4 in the second direction Y. The edge portion E4 of the sealing layer SE13 is spaced apart from the sealing layer SE12 of the pixel PX3. That is, the slit-shaped areas ST respectively extend between the edge portion E4 and the sealing layer SE12.

In this manner, in the illustrated example, the slit-shaped areas ST respectively extend between the edge portion E2 and the sealing layer SE12, between the edge portion E3 and the sealing layer SE11, and between the edge portion E4 and the sealing layer SE12 around the sealing layer SE13 of the pixel PX4. In the same manner, the sealing layer SE13 of the other pixels have the slit-shaped area ST along the three edge portions.

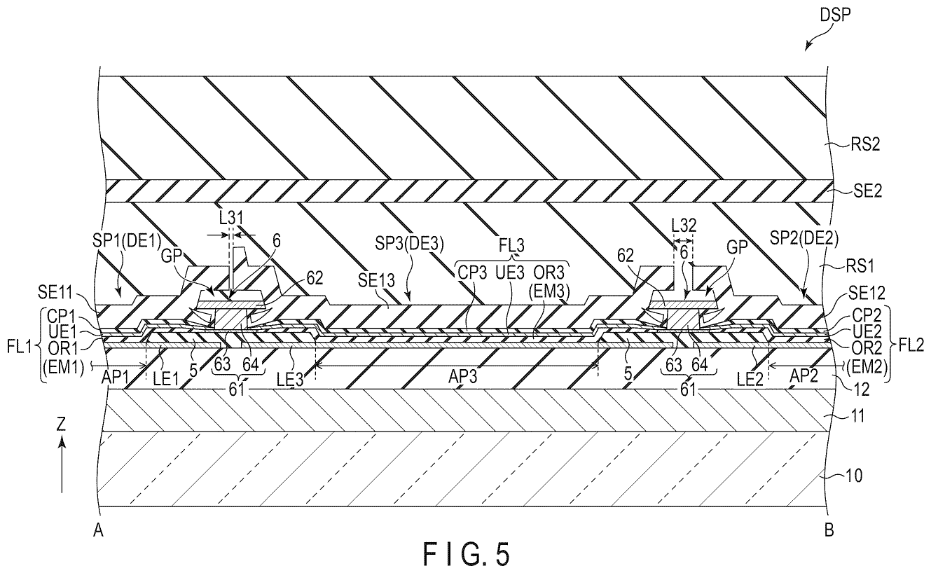

FIG. 5 is a schematic cross-sectional view of the display device DSP along the A-B line of FIG. 4.

A circuit layer 11 is provided on the substrate 10. The circuit layer 11 includes various circuits such as the pixel circuits 1 shown in FIG. 1, various lines such as the scanning line GL, the signal line SL, and the power line PL, and various insulating layers.

The organic insulating layer 12 is provided on the circuit layer 11. For example, the organic insulating layer 12 is formed to planarize irregularities formed by the circuit layer 11.

The lower electrode LE1 of the subpixel SP1, the lower electrode LE2 of the subpixel SP2, and the lower electrode LE3 of the subpixel SP3 are provided on the organic insulating layer 12 and are spaced apart from each other.

The inorganic insulating layer 5 is provided on the organic insulating layer 12 and the lower electrodes LE1, LE2, and LE3. The aperture AP1 in the inorganic insulating layer 5 overlaps the lower electrode LE1. Further, the aperture AP2 overlaps the lower electrode LE2, and the aperture AP3 overlaps the lower electrode LE3. The peripheral portions of the lower electrodes LE1, LE2, and LE3 are covered with the inorganic insulating layer 5. The lower electrodes LE1, LE2, and LE3 are connected to the pixel circuits 1 of the respective subpixels SP1, SP2, and SP3 through the contact holes provided in the organic insulating layer 12. The illustration of the contact hole in the organic insulating layer 12 is omitted.

The partition 6 is formed in an overhang shape and comprises a lower portion 61 having conductivity and provided on the inorganic insulating layer 5 and an upper portion 62 provided on the lower portion 61.

In the illustrated example, the lower portion 61 comprises a bottom layer 63 provided on the inorganic insulating layer 5 and a stem layer 64 provided between the bottom layer 63 and the upper portion 62. The bottom layer 63 is thinner than the stem layer 64. The bottom layer 63 has the width greater than that of the stem layer 64. The both end portions of the bottom layer 63 protrude relative to the side surfaces of the stem layer 64.

The upper portion 62 is provided on the stem layer 64. The upper portion 62 has the width greater than that of the stem layer 64. The both end portions of the upper portion 62 protrude relative to the side surfaces of the stem layer 64. In the present specification, the side surfaces of the stem layer 64 are assumed to be the side surfaces of the stem layer 64 that extend between the bottom layer 63 and the upper portion 62. In the illustrated example, the upper portion 62 has the width greater than that of the bottom layer 63. The bottom layer 63 may have a width greater than that of the upper portion 62.

In the display element DE1, the organic layer OR1 contacts the lower electrode LE1 through the aperture AP1 and covers the lower electrode LE1 exposed from the aperture AP1. The peripheral portion of the organic layer OR1 is located on the inorganic insulating layer 5. The upper electrode UE1 covers the organic layer OR1 and contacts the lower portion 61.

In the display element DE2, the organic layer OR2 contacts the lower electrode LE2 through the aperture AP2 and covers the lower electrode LE2 exposed from the aperture AP2. The peripheral portion of the organic layer OR2 is located on the inorganic insulating layer 5. The upper electrode UE2 covers the organic layer OR2 and contacts the lower portion 61.

In the display element DE3, the organic layer OR3 contacts the lower electrode LE3 through the aperture AP3 and covers the lower electrode LE3 exposed from the aperture AP3. The peripheral portion of the organic layer OR3 is located on the inorganic insulating layer 5. The upper electrode UE3 covers the organic layer OR3 and contacts the lower portion 61.

The contact between each of the upper electrodes UE1, UE2, and UE3 and the lower portion 61 includes a case where each of the upper electrodes UE1, UE2, and UE3 directly contacts the upper surface of the bottom layer 63 and a case where each of the upper electrodes UE1, UE2, and UE3 directly contacts the upper surface of the bottom layer 63 and further directly contacts the side surfaces of the stem layer 64. In this specification, the upper surface of the bottom layer 63 is assumed to have, of the bottom layer 63, the surface that directly contacts the stem layer 64 and the surface that protrudes relative to the stem layer 64 and faces the upper portion 62.

The cap layer CP1 is provided on the upper electrode UE1. The cap layer CP2 is provided on the upper electrode UE2. The cap layer CP3 is provided on the upper electrode UE3. The cap layers CP1, CP2 and CP3 function as optical adjustment layers, which improve the extraction efficiency of light emitted from the organic layers OR1, OR2, and OR3, respectively. The cap layers CP1, CP2, and CP3 may be omitted.

The sealing layer SE11 is provided on the cap layer CP1, contacts the partition 6, and continuously covers each member of the subpixel SP1. The sealing layer SE11 contacts the stem layer 64 and the upper portion 62 of the partition 6 that surrounds the display element DE1.

The sealing layer SE12 is provided on the cap layer CP2, contacts the partition 6, and continuously covers each member of the subpixel SP2. The sealing layer SE12 contacts the stem layer 64 and the upper portion 62 of the partition 6 that surrounds the display element DE2.

The sealing layer SE13 is provided on the cap layer CP3, contacts the partition 6, and continuously covers each member of the subpixel SP3. The sealing layer SE13 contacts the stem layer 64 and the upper portion 62 of the partition 6 that surrounds the display element DE3.

Each of the sealing layers SE11, SE12, and SE13 extends above the partition 6. Further, the end portions of the sealing layers SE11, SE12, and SE13 are located above the partition 6.

In the illustrated example, the sealing layer SE13 is close to the sealing layer SE11 and rises up in the vicinity of the edge portion of the sealing layer SE11 above the partition 6 between the subpixels SP1 and SP3. The sealing layer SE13 may contact the sealing layer SE11.

Further, the sealing layer SE13 is spaced apart from the sealing layer SE12 above the partition 6 between the subpixels SP2 and SP3. A distance L32 between the sealing layers SE13 and SE12 is greater than a distance L31 between the sealing layers SE13 and SE11 (L32>L31). The distance L32 is at least 10 times the distance L31. In one example, the distance L32 is 5 μm or more. Furthermore, the distance L31 is 0.5 μm or less.

No reflective layers are provided between the sealing layer SE11 and the partition 6, between the sealing layer SE12 and the partition 6, and between the sealing layer SE13 and the partition 6. Here, the reflective layers are thin films capable of reflecting external light such as a metal layer or a dielectric multilayer film.

Each of the stacked films FL1, FL2, and FL3 is not provided on the partition 6. Cavities are formed between the sealing layer SE11 and the partition 6, between the sealing layer SE12 and the partition 6, and between the sealing layer SE13 and the partition 6.

The transparent resin layer RS1 covers the partition 6 and the sealing layers SE11, SE12, and SE13. The resin layer RS1 fills cavities formed between the sealing layer SE11 and the partition 6, between the sealing layer SE12 and the partition 6, and between the sealing layer SE13 and the partition 6.

The sealing layer SE2 covers the resin layer RS1. The transparent resin layer RS2 is provided on the sealing layer SE2.

Each of the inorganic insulating layer 5, the sealing layers SE11, SE12, and SE13 and the sealing layer SE2 is formed of, for example, an inorganic insulating material such as a silicon nitride (SiNx), a silicon oxide (SiOx), a silicon oxynitride (SiON) or an aluminum oxide (Al₂O₃). For example, the inorganic insulating layer 5 is formed of a silicon oxynitride, and each of the sealing layers SE11, SE12, SE13, and SE2 is formed of a silicon nitride.

The lower portion 61 of the partition 6 is formed of a conductive material and is electrically connected to the upper electrodes UE1, UE2 and UE3. The bottom layer 63 is formed of, for example, a titanium-based material such as titanium or a titanium compound. The stem layer 64 is formed of a material different from those of the bottom layer 63 and the upper portion 62, and is formed of, for example, an aluminum-based material such as aluminum or an aluminum compound.

The upper portion 62 of the partition 6 is formed of, for example, a conductive material. However, the upper portion 62 may be formed of an insulating material. The upper portion 62 is formed of a material different from that of the lower portion 61. For example, the upper portion 62 is a multilayer body having a first thin film located on the stem layer 64 and formed of a titanium-based material such as titanium or a titanium compound and a second thin film located on the first thin film and formed of an oxide conductive material such as an indium tin oxide (ITO). The second thin film has a function of suppressing reflection of external light in the partition 6.

For example, each of the lower electrodes LE1, LE2, and LE3 is a multilayer body having a transparent layer formed of an oxide conductive material such as an indium tin oxide (ITO) and a reflective layer formed of a metal material such as silver. In one example, each of the lower electrodes LE1, LE2, and LE3 is a multilayer body having a reflective layer between a pair of transparent layers.

The organic layer OR1 has the light emitting layer EM1. The organic layer OR2 has the light emitting layer EM2. The organic layer OR3 has the light emitting layer EM3. Each of the organic layers OR1, OR2, and OR3 has a plurality of functional layers such as a hole injection layer, a hole transport layer, an electron blocking layer, a hole blocking layer, an electron transport layer, and an electron injection layer.

The upper electrodes UE1, UE2, and UE3 are formed of, for example, a metal material such as an alloy of magnesium and silver (MgAg).

Each of the cap layers CP1, CP2, and CP3 is a multilayer body having a plurality of thin films. All of the thin films are transparent and have refractive indices different from each other.

None of the organic layers OR1, OR2, and OR3, the upper electrodes UE1, UE2, and UE3, and the cap layers CP1, CP2, and CP3, which can function as the reflective layers, are provided on the upper portion 62 of the partition 6.

The circuit layer 11, the organic insulating layer 12, the inorganic insulating layer 5, and the partition 6, which are illustrated, are provided across the display area DA and the surrounding area SA.

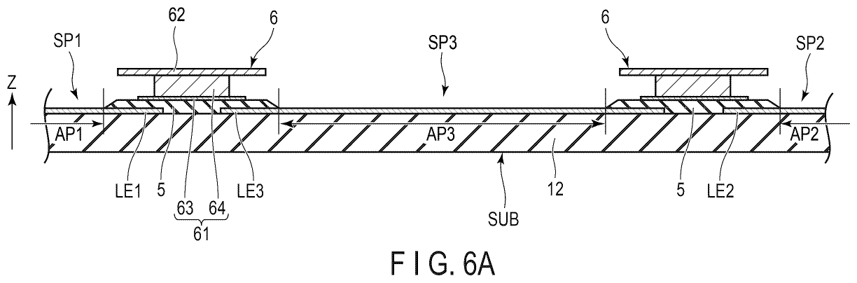

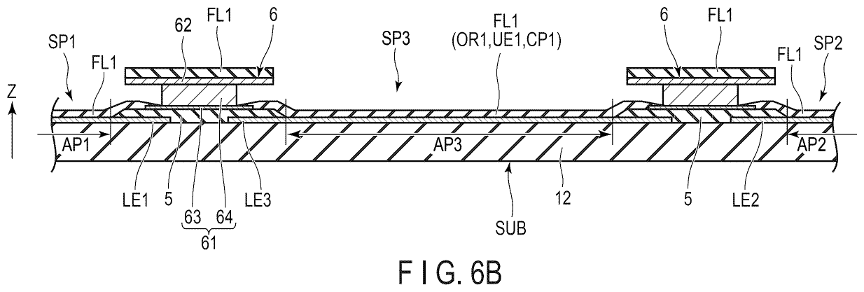

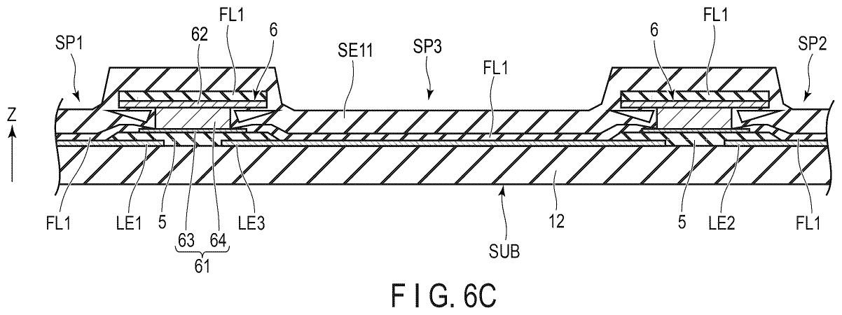

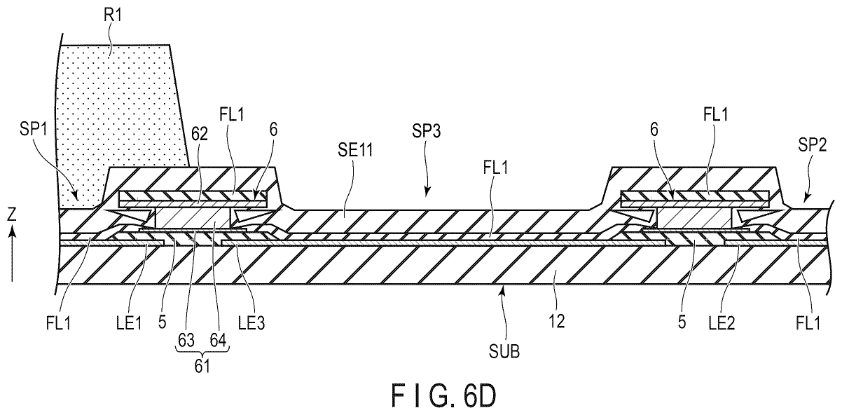

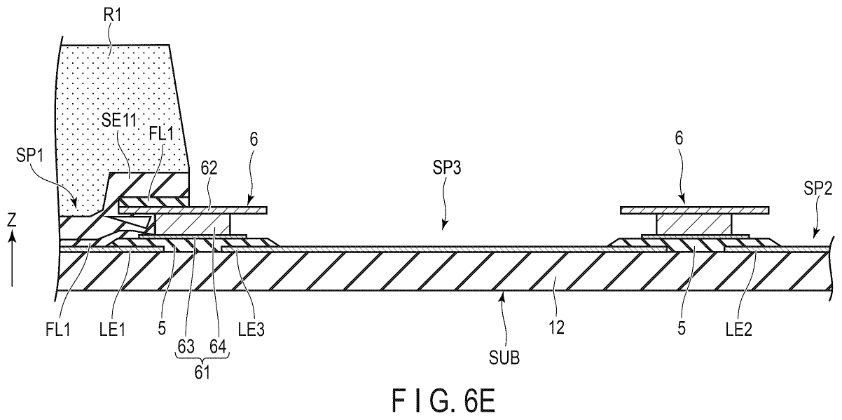

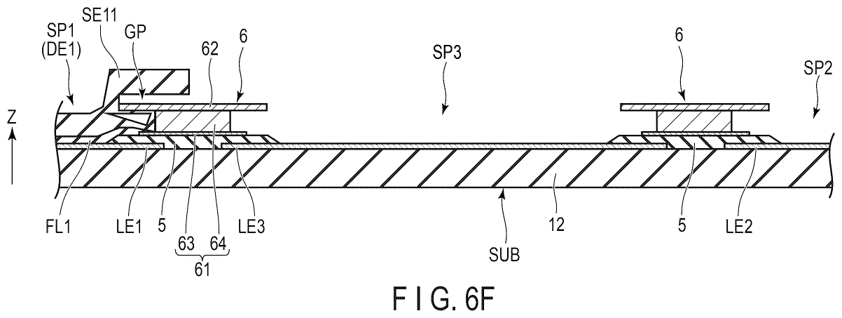

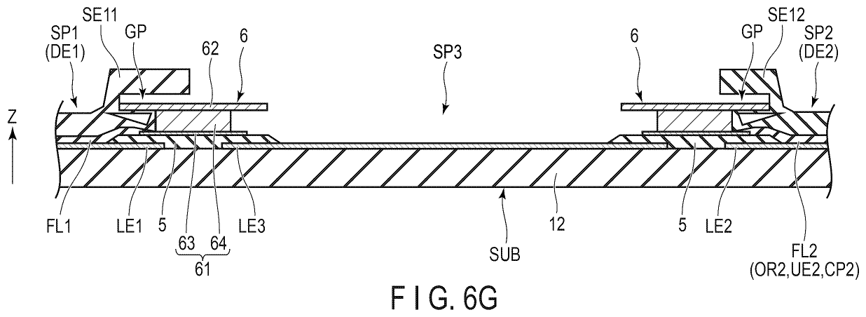

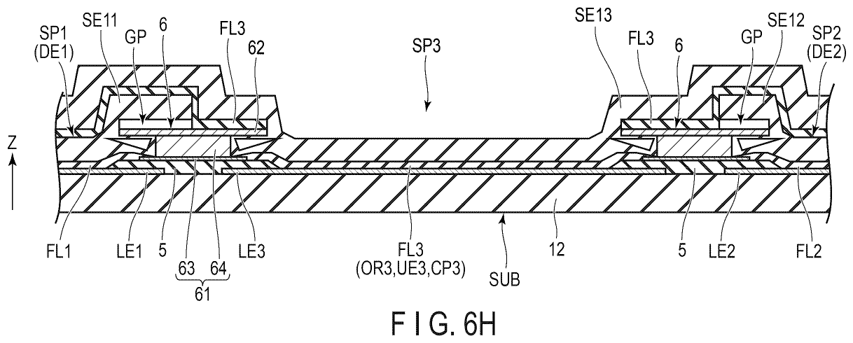

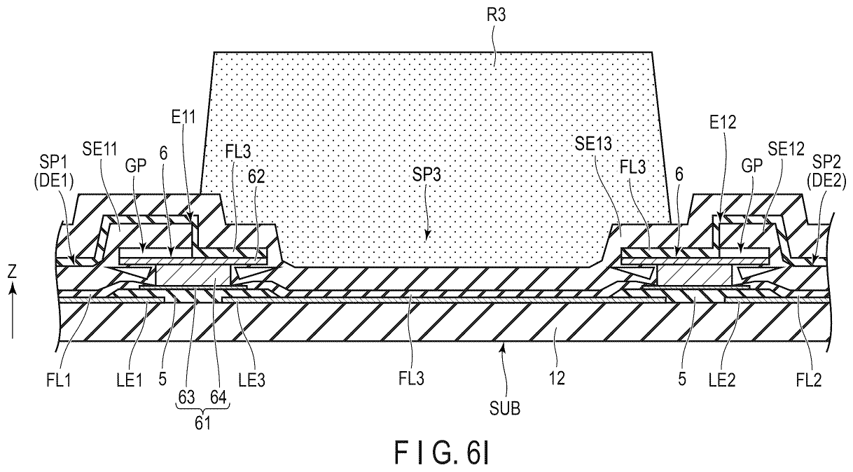

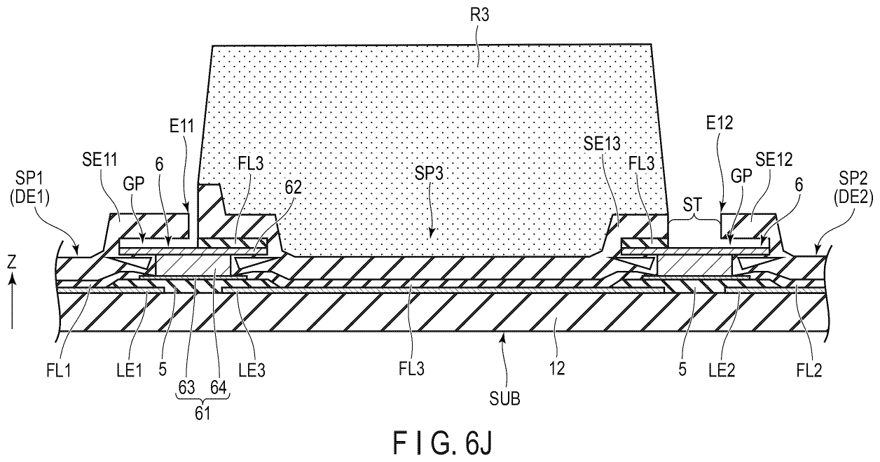

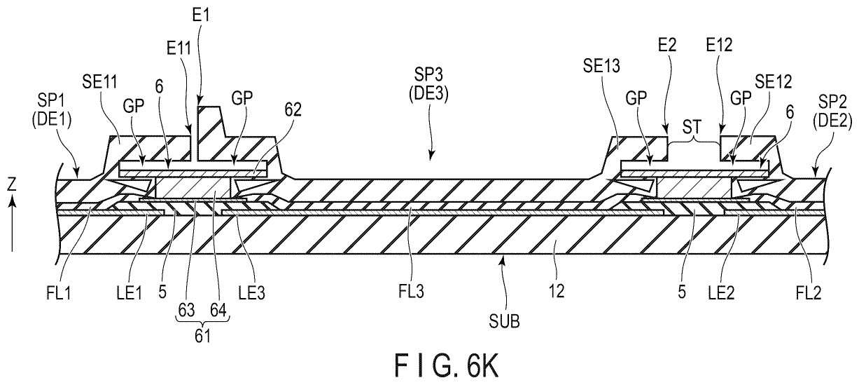

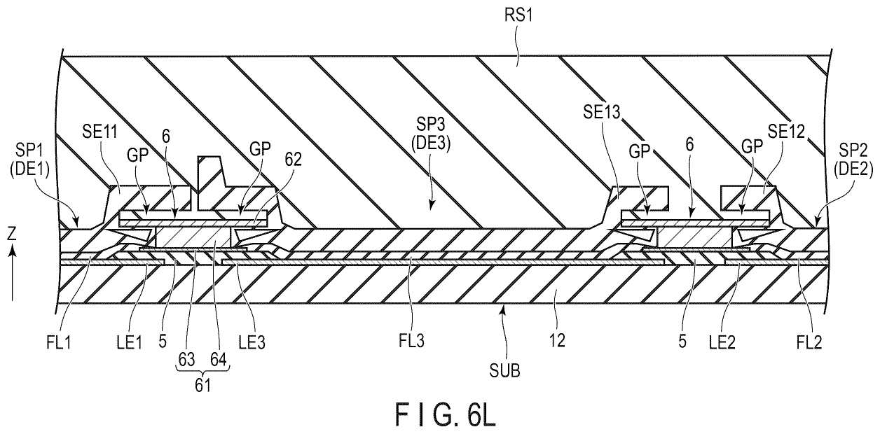

Next, a manufacturing method of the display device DSP will be described. FIG. 6A to FIG. 6L are cross-sectional views of a processing substrate SUB along the A-B line of FIG. 4 and omits elements below the organic insulating layer 12.

First, the processing substrate SUB is prepared as shown in FIG. 6A. The process of preparing the processing substrate SUB includes the process of forming the lower electrode LE1 of the subpixel SP1, the lower electrode LE2 of the subpixel SP2, and the lower electrode LE3 of the subpixel SP3 on the organic insulating layer 12, the process of forming the inorganic insulating layer 5 having the apertures AP1, AP2, and AP3 overlapping the respective lower electrodes LE1, LE2, and LE3, and the process of forming the partition 6 having an overhang shape and including the lower portion 61 located on the inorganic insulating layer 5 and the upper portion 62 located on the lower portion 61. The partition 6 may be formed after the formation of the inorganic insulating layer 5 having the apertures AP1, AP2, and AP3. Alternatively, the apertures AP1, AP2, and AP3 may be formed on the inorganic insulating layer 5 after the formation of the partition 6.

Subsequently, the display element DE1 is formed.

First, the stacked film FL1 is formed on the processing substrate SUB by performing vapor deposition using the partition 6 as a mask as shown in FIG. 6B. The stacked film FL1 is formed on the lower electrodes LE1, LE2, and LE3 and the partition 6. The stacked film FL1 includes the organic layer OR1 including the light emitting layer EM1, the upper electrode UE1, and the cap layer CP1. The organic layer OR1, the upper electrode UE1, and the cap layer CP1 are successively formed by an evaporation device in a vacuum state. The upper electrode UE1 is formed of an alloy of magnesium and silver.

The stacked film FL1 is divided by the partition 6 having an overhang shape. That is, the portion that is provided on the lower electrodes LE1, LE2, and LE3 of the stacked film FL1 are spaced apart from the portion that is provided on the partition 6.

Subsequently, the sealing layer SE11 continuously covering the stacked film FL1 and the partition 6 is formed as shown in FIG. 6C. The sealing layer SE11 is formed by depositing inorganic insulating materials (for example, a silicon nitride) on the processing substrate SUB in a Chemical Vapor Deposition (CVD) device.

The stacked film FL1 and the sealing layer SE11 are substantially formed in the entire processing substrate SUB and are provided in the subpixels SP2 and SP3 as well as the subpixel SP1 in the display area DA.

Subsequently, a resist R1 patterned into a predetermined shape is formed on the sealing layer SE11 as shown in FIG. 6D. The resist R1 overlaps the subpixel SP1 and a portion of the partition 6 around the subpixel SP1.

Subsequently, patterning is performed on the sealing layer SE11 and the stacked film FL1 using the resist R1 as a mask as shown in FIG. 6E. After removing the sealing layer SE11 exposed from the resist R1 by performing various etching using the resist R1 as a mask, the cap layer CP1, the upper electrode UE1, and the organic layer OR1 included in the stacked film FL1 are removed successively. These patterning processes make the lower electrode LE2 of the subpixel SP2 and the lower electrode LE3 of the subpixel SP3 exposed.

Subsequently, the resist R1 is removed as shown in FIG. 6F. This process forms the display element DE1 in the subpixel SP1. Further, the stacked film FL1 formed on the partition 6 is removed in the processes between the patterning of the stacked film FL1 and the removal of the resist R1. Thus, the stacked film FL1 including the upper electrode UE1 is not provided on the partition 6. Thus, a cavity GP is formed between the sealing layer SE11 and the partition 6.

Subsequently, the display element DE2 is formed as shown in FIG. 6G. The procedure of forming the display element DE2 is the same as that of forming the display element DE1. That is, the stacked film FL2 is formed on the lower electrode LE2. The stacked film FL2 includes the organic layer OR2 including the light emitting layer EM2, the upper electrode UE2, and the cap layer CP2. The light emitting layer EM2 is formed of a material different from the light emitting layer EM1. In the same manner as the upper electrode UE1, the upper electrode UE2 is formed of an alloy of magnesium and silver.

Subsequently, the sealing layer SE12 is formed on the stacked film FL2. Subsequently, a resist is formed on the sealing layer SE12. Then, patterning using this resist as a mask is performed. This sequentially removes the sealing layer SE12 and the stacked film FL2 exposed from the resist. Subsequently, the resist is removed.

This process forms the display element DE2 in the subpixel SP2 and makes the lower electrode LE3 of the subpixel SP3 exposed. Further, the stacked film FL2 formed on the partition 6 is removed in the processes between the patterning of the stacked film FL2 and the removal of the resist. Thus, the stacked film FL2 including the upper electrode UE2 is not provided on the partition 6. Thus, the cavity GP is formed between the sealing layer SE12 and the partition 6.

Next, the display element DE3 is formed as shown in FIG. 6H. The procedure of forming the display element DE3 is the same as that of forming the display element DE1. That is, the stacked film FL3 is formed on the lower electrode LE3. At this time, the stacked film FL3 is formed on the sealing layers SE11 and SE12 and the partition 6 as well. The stacked film FL3 is formed by vapor deposition using the partition 6 as a mask and thus is divided by the partition 6 having an overhang shape. That is, the portion that is provided on the lower electrode LE3 of the stacked film FL3 is spaced apart from the portion that is provided on the partition 6.

The stacked film FL3 includes the organic layer OR3 including the light emitting layer EM3, the upper electrode UE3, and the cap layer CP3. The light emitting layer EM3 is formed of a material different from the light-emitting layers EM1 and EM2. For example, the light emitting layer EM3 is formed of a material that emits light in the red wavelength range. In the same manner as the upper electrode UE1, the upper electrode UE3 is formed of an alloy of magnesium and silver.

Subsequently, the sealing layer SE13 is formed on the stacked film FL3 by the same method as the one for the sealing layer SE11.

Then, a resist R3 patterned into a predetermined shape is formed on the sealing layer SE13 as shown in FIG. 6I. The resist R3 overlaps the subpixel SP3 and a portion of the partition 6 around the subpixel SP3. At this time, the resist R3 is formed such that the distance from the resist R3 to an edge portion E12 of the sealing layer SE12 is greater than the distance from the resist R3 to an edge portion E11 of the sealing layer SE11. The resist R3 may overlap the edge portion E11. In contrast, the resist R3 is formed to be spaced apart from the edge portion E12.

Subsequently, patterning is performed on the sealing layer SE13 and the stacked film FL3 using the resist R3 as a mask as shown in FIG. 6J. After removing the sealing layer SE13 exposed from the resist R3 by performing various etching using the resist R3 as a mask, the cap layer CP3, the upper electrode UE3, and the organic layer OR3 included in the stacked film FL3 are removed successively. These patterning make the sealing layer SE11 of the subpixel SP1 and the sealing layer SE12 of the subpixel SP2 exposed. The resist R3 is formed to be spaced from the edge portion E12. Thus, the slit-shaped area ST having a relatively greater width, is formed between the sealing layers SE12 and SE13.

Then, the resist R3 is removed as shown in FIG. 6K. This forms the display element DE3 in the subpixel SP3.

Further, the stacked film FL3 formed on the partition 6 is removed by etching liquid or etching gas that has penetrated from the large area ST between the edge portion E2 of the sealing layer SE13 and the edge portion E12 of the sealing layer SE12 in the processes between the patterning of the stacked film FL3 and the removal of the resist R3. Thus, the stacked film FL3 including the upper electrode UE3 is not provided on the partition 6. Thus, the cavity GP is formed between the sealing layer SE13 and the partition 6.

The above-described manufacturing process assumes a case where the display element DE1 is formed firstly, the display element DE2 is formed secondly, and the display element DE3 is formed lastly. However, the formation order of the display elements DE1, DE2, and DE3 is not limited to this example.

Then, an organic insulating material is applied on the sealing layers SE11, SE12, and SE13 and cured to form the resin layer RS1 as shown in FIG. 6L. At this time, the applied organic insulating materials fill cavities formed between the partition 6 and the sealing layer SE11, between the partition 6 and the sealing layer SE12, and between the partition 6 and the sealing layer SE13.

Then, the sealing layer SE2 is formed by stacking an inorganic insulating material (for example, a silicon nitride). Then, an organic insulating material is applied and cured. This forms the resin layer RS2.

The display device DSP is completed through these processes.

As described above, in the process of forming the display element DE1, the entire circumference of the stacked film FL1 formed on the partition 6 is exposed to a wet etching solution or a dry etching gas. Thus, the stacked film FL1 on the partition 6 is removed in the process of forming the display element DE1.

In the process of forming the display element DE2 to be adjacent to the display element DE1, the stacked film FL2 formed on the partition 6 is exposed to an etching solution or an etching gas except the edge portion adjacent to the display element DE1. Thus, the stacked film FL2 on the partition 6 is removed in the process of forming the display element DE2.

In the process of forming the display element DE3 to be adjacent to the display elements DE1 and DE2, the slit-shaped area ST is formed between the sealing layer SE12 of the display element DE2 and the display element DE3 of the sealing layer SE13. Thus, the stacked film FL3 formed on the partition 6 is exposed to an etching solution or an etching gas that has penetrated from the area ST. An etching solution or an etching gas flows around the entire circumference of the display element DE3 from the area ST. This removes the stacked film FL3 on the partition 6.

Next, the following describes on comparative examples.

First, after forming the display elements DE1 and DE2 as described with reference to FIG. 6A to FIG. 6H, the stacked film FL3 and the sealing layer SE13 are formed.

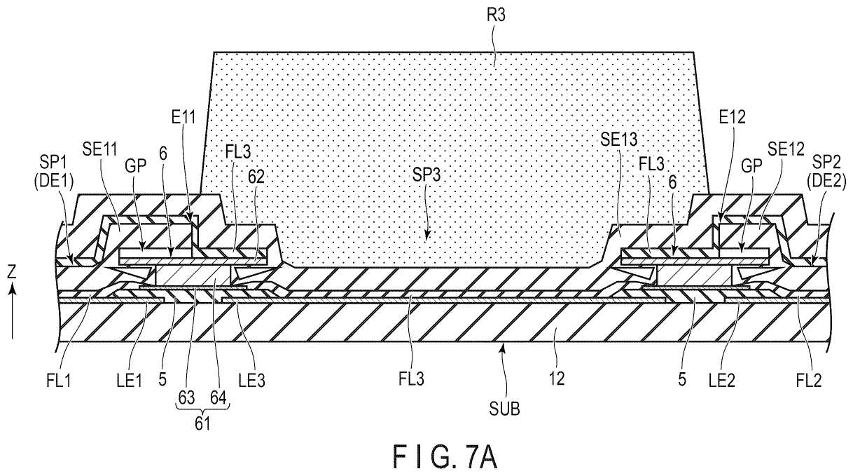

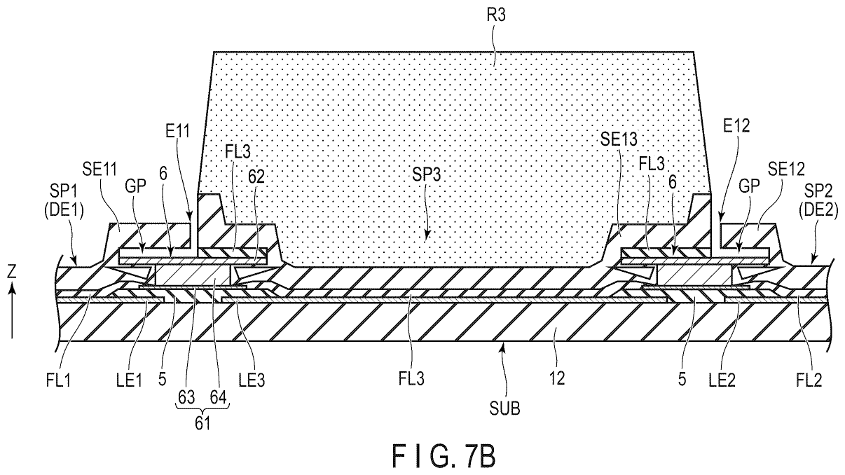

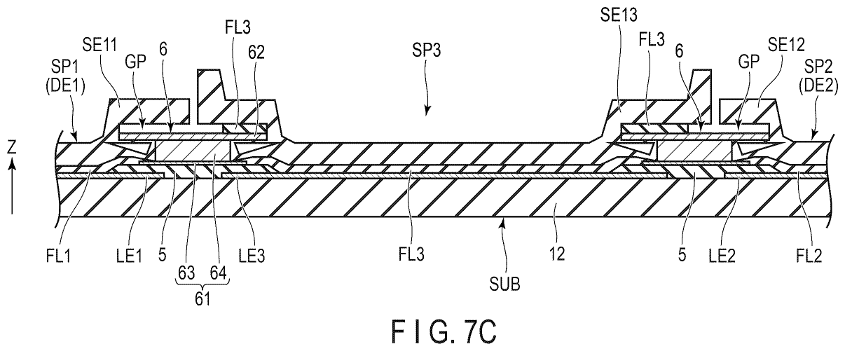

Then, the resist R3 patterned into a predetermined shape is formed on the sealing layer SE13 as shown in FIG. 7A. The resist R3 overlaps the subpixel SP3 and a portion of the partition 6 around the subpixel SP3. At this time, the resist R3 is formed to be close to the edge portion E11 of the sealing layer SE11 and the edge portion E12 of the sealing layer SE12.

Subsequently, patterning is performed on the sealing layer SE13 and the stacked film FL3 using the resist R3 as a mask as shown in FIG. 7B. As described above, the resist R3 is close to the edge portions E11 and E12. Thus, at this time, the wide area ST as shown in FIG. 6J is less likely to be formed between the sealing layers SE13 and SE11 and between the sealing layers SE13 and SE12.

Then, the resist R3 is removed as shown in FIG. 7C.

In this comparative example, in the process of forming the display element DE3 to be adjacent to the display elements DE1 and DE2, the gaps between the sealing layers SE11 and SE13 and between the sealing layers SE12 and SE13 are both small. Thus, an etching solution or an etching gas is unlikely to intrude these gaps. Thus, the stacked film FL3 formed on the partition 6 is less likely to be exposed to an etching solution or an etching gas and be removed. When a portion of the stacked film FL3 remains on the partition 6 as shown in FIG. 7C, the reflective layer (for example, the upper electrode UE3) included in the stacked film FL3 may reflect external light.

External light is reflected in a local area of the display area DA in the configuration in which no stacked films FL1 and FL2 are respectively provided on the partition 6 surrounding the display element DE1 and the partition 6 surrounding the display element DE2, but a portion of the stacked film FL3 is provided on the partition 6 surrounding the display element DE3. This configuration causes deterioration of the display quality.

In the present embodiment, none of the stacked films FL1, FL2, and FL3 are provided on the partition 6. This suppresses undesirable reflection of external light and improves the display quality.

Next, other configuration examples will be described. The same elements as in the above configuration example are denoted by the same reference numerals and their detailed explanations are omitted in some cases.

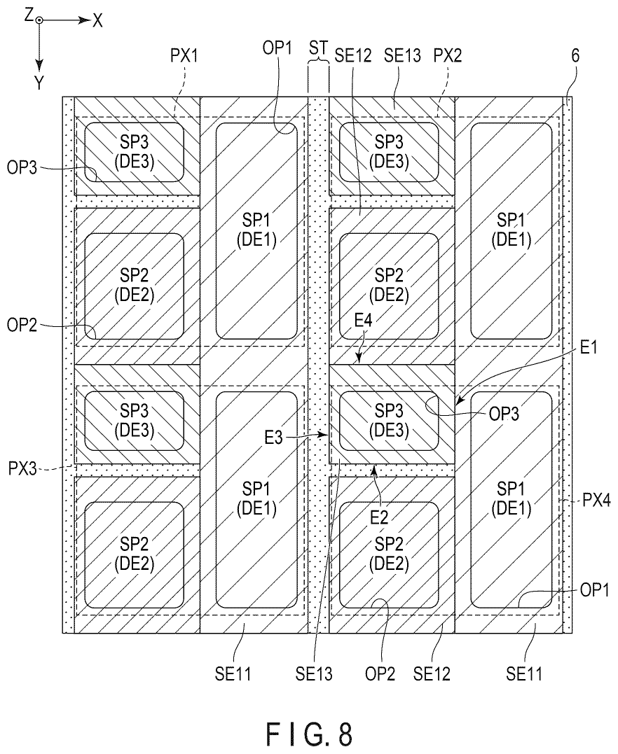

FIG. 8 is a view showing another configuration example of the layout of the sealing layers SE11, SE12, and SE13.

The configuration example shown in FIG. 8 differs from the configuration example shown in FIG. 4 in that the distance between one of the sealing layers SE12 and SE13 in the second direction Y is greater than the distance between the sealing layers SE12 and SE13 in the second direction Y.

The following describes on the pixels PX2 and PX4 adjacent to each other in the second direction Y.

The sealing layer SE13 of the pixel PX4 is located between the sealing layer SE12 of the pixel PX2 and the sealing layer SE12 of the pixel PX4 in the second direction Y. The edge portion E4 of the sealing layer SE13 is close to the sealing layer SE12 of the pixels PX2 and may contact the sealing layer SE12. The edge portion E2 of the sealing layer SE13 is spaced apart from the sealing layer SE12 of the pixel PX4. That is, the slit-shaped areas ST respectively extend between the edge portion E2 and the sealing layer SE12.

In this manner, in the illustrated example, the slit-shaped areas ST respectively extend between the edge portion E2 and the sealing layer SE12 and between the edge portion E3 and the sealing layer SE11 of the pixel PX3 around the sealing layer SE13 of the pixel PX4. In the same manner, the sealing layer SE13 of the other pixels have the slit-shaped area ST along the two edge portions.

In this configuration example as well, the stacked film FL3 on the partition 6 is exposed to an etching solution or an etching gas that has penetrated from the area ST in the formation of the display element DE3. Thus, the same effects as the above configuration example can be achieved.

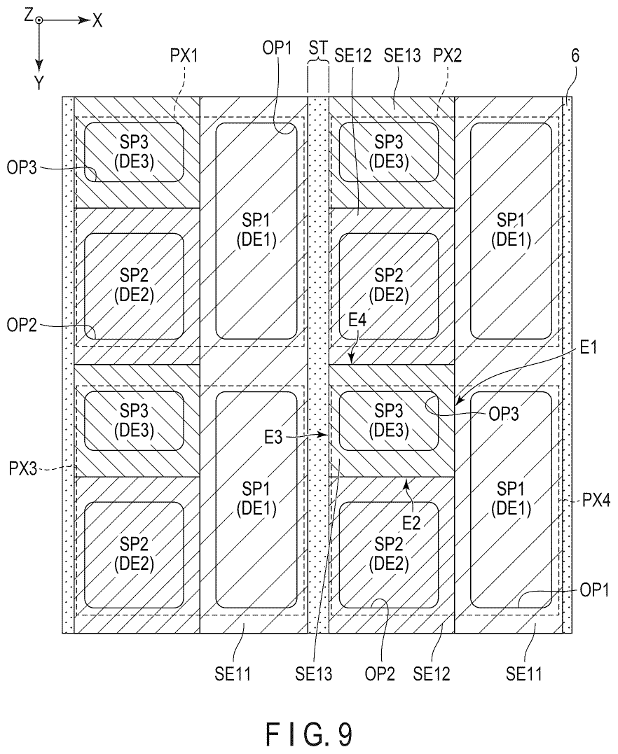

FIG. 9 is a view showing another configuration example of the layout of the sealing layers SE11, SE12, and SE13.

The configuration example shown in FIG. 9 differs from the configuration example shown in FIG. 4 in that, in the second direction Y, the edge portion E2 of the sealing layer SE13 is close to one sealing layer SE12, and the edge portion E4 of the sealing layer SE13 is close to the other sealing layer SE12.

For example, with respect to the sealing layer SE13 of the pixel PX4, the edge portion E2 of the sealing layer SE13 is close to the sealing layer SE12 of the pixel PX4, and the edge portion E4 of the sealing layer SE13 is close to the sealing layer SE12 of the pixel PX2. The slit-shaped areas ST respectively extend between the edge portion E3 and the sealing layer SE11 of the pixel PX3 around this sealing layer SE13. In the same manner, the sealing layer SE13 of the other pixels have the slit-shaped area ST along one edge portion.

This configuration example can achieve the same effect as in the above configuration examples.

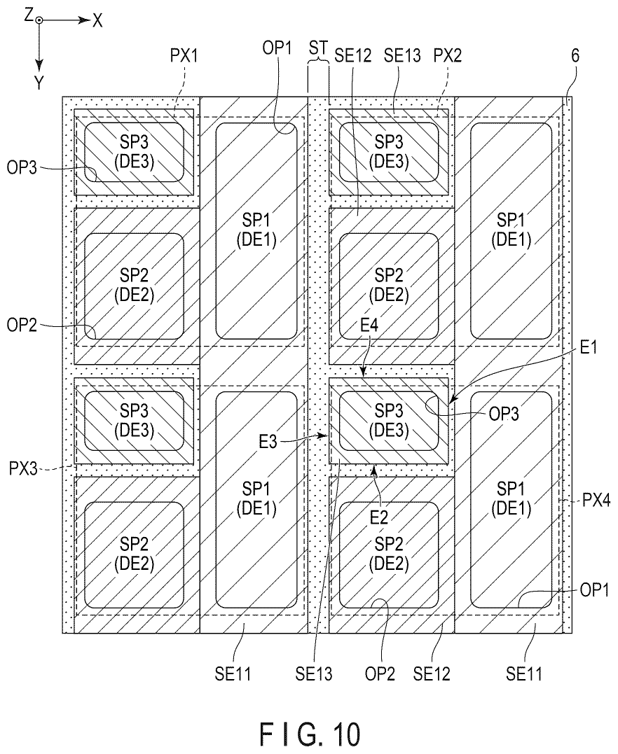

FIG. 10 is a view showing another configuration example of the layout of the sealing layers SE11, SE12, and SE13.

The configuration example shown in FIG. 10 differs from the configuration example shown in FIG. 4 in that the slit-shaped area ST is formed around the entire circumference of the sealing layer SE13.

For example, around the sealing layer SE13 of the pixel PX4, the slit-shaped areas ST respectively extend between the edge portion E1 and the sealing layer SE11 of the pixel PX4, between the edge portion E2 and the sealing layer SE12 of the pixel PX4, between the edge portion E3 and the sealing layer SE11 of the pixel PX3, and between the edge portion E4 and the sealing layer SE12 of the pixel PX2. In the same manner, the sealing layer SE13 of the other pixels have the slit-shaped area ST along the four edge portions.

This configuration example can achieve the same effect as in the above configuration examples.

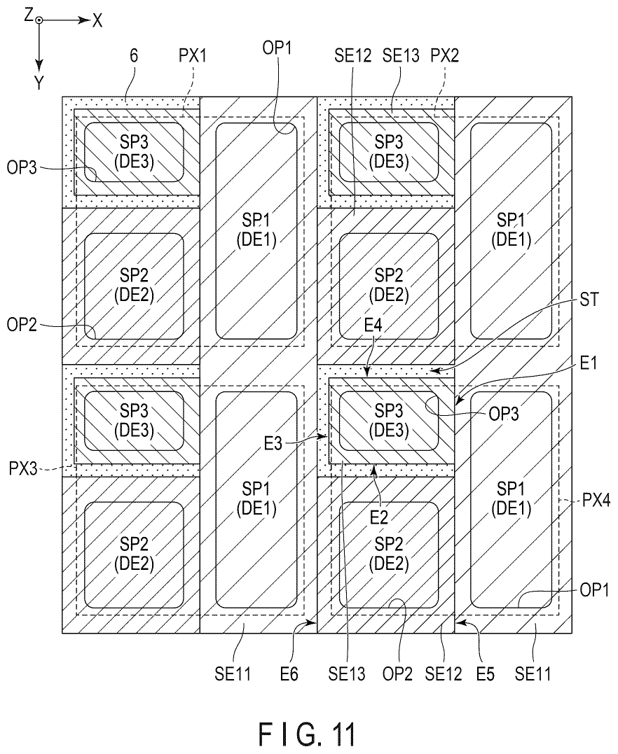

FIG. 11 is a view showing another configuration example of the layout of the sealing layers SE11, SE12, and SE13.

The configuration example shown in FIG. 11 differs from the configuration example shown in FIG. 4 in that, in the first direction X, the sealing layer SE12 is close to one sealing layer SE11 and the other sealing layer SE11.

For example, on the sealing layer SE12 of the pixel PX4, the edge portion E5 is close to the sealing layer SE11 of the pixel PX4, and the edge portion E6 is close to the sealing layer SE11 of the pixel PX3. Around the sealing layer SE13 of the pixel PX4, the slit-shaped areas ST respectively extend between the edge portion E2 and the sealing layer SE12 of the pixel PX4, between the edge portion E3 and the sealing layer SE11 of the pixel PX3, between the edge portion E4 and the sealing layer SE12 of the pixel PX2. In the same manner, the sealing layer SE13 of the other pixels have the slit-shaped area ST along the three edge portions.

This configuration example can achieve the same effect as in the above configuration examples.

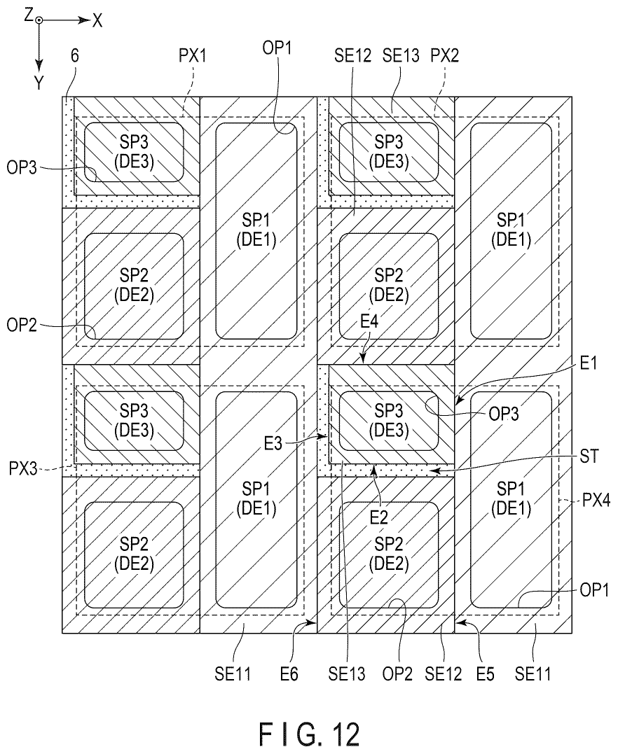

FIG. 12 is a view showing another configuration example of the layout of the sealing layers SE11, SE12, and SE13.

The configuration example shown in FIG. 12 differs from the configuration example shown in FIG. 11 in that the distance between one pair of the sealing layers SE12 and SE13 in the second direction Y is greater than the distance between the other pair of the sealing layers SE12 and SE13 in the second direction Y.

For example, on the sealing layer SE13 of the pixel PX4, the edge portion E2 is close to the sealing layer SE12 of the pixel PX4, and the edge portion E4 is close to the sealing layer SE12 of the pixel PX2. The slit-shaped areas ST respectively extend between the edge portion E2 and the sealing layer SE12 of the pixel PX4 and between the edge portion E3 and the sealing layer SE11 of the pixel PX3 around the sealing layer SE13. In the same manner, the sealing layer SE13 of the other pixels have the slit-shaped area ST along the two edge portions.

This configuration example can achieve the same effect as in the above configuration examples.

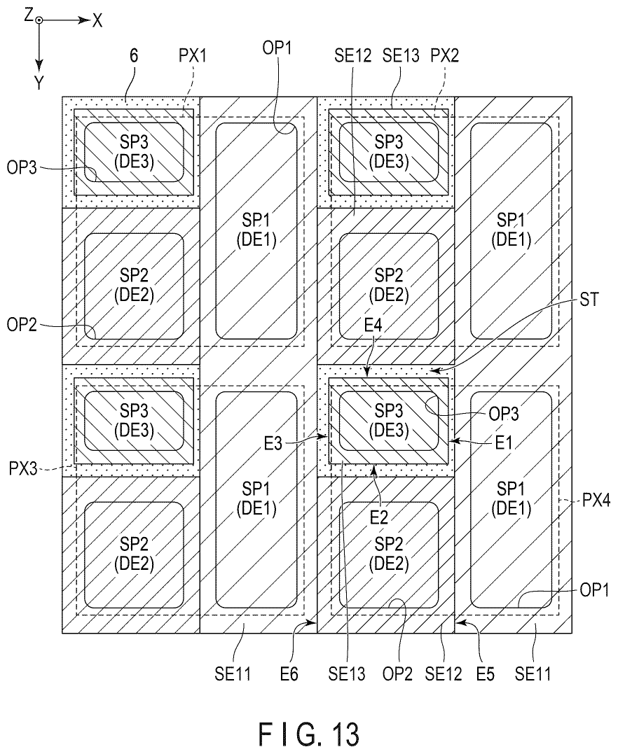

FIG. 13 is a view showing another configuration example of the layout of the sealing layers SE11, SE12, and SE13.

The configuration example shown in FIG. 13 differs from the configuration example shown in FIG. 11 in that the slit-shaped area ST is formed around the entire circumference of the sealing layer SE13.

For example, around the sealing layer SE13 of the pixel PX4, the slit-shaped areas ST respectively extend between the edge portion E1 and the sealing layer SE11 of the pixel PX4, between the edge portion E2 and the sealing layer SE12 of the pixel PX4, between the edge portion E3 and the sealing layer SE11 of the pixel PX3, and between the edge portion E4 and the sealing layer SE12 of the pixel PX2. In the same manner, the sealing layer SE13 of the other pixels have the slit-shaped area ST along the four edge portions.

This configuration example can achieve the same effect as in the above configuration examples.

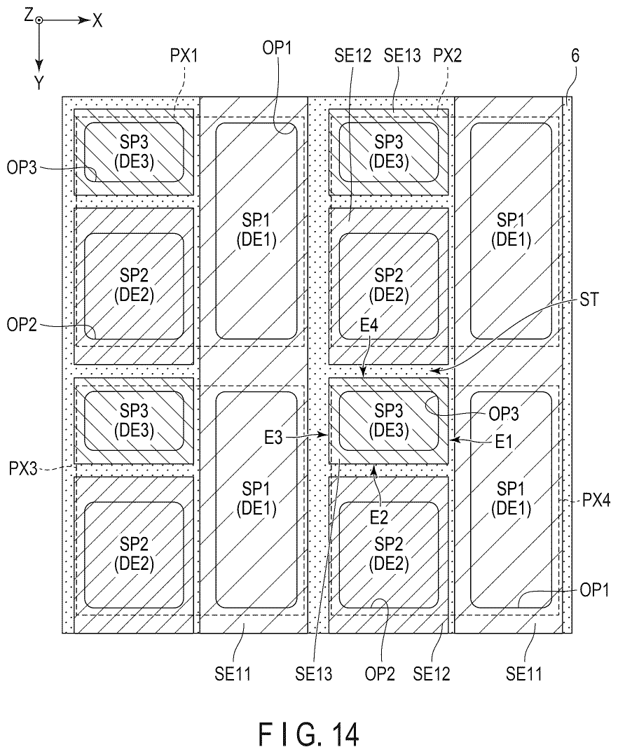

FIG. 14 is a view showing another configuration example of the layout of the sealing layers SE11, SE12, and SE13.

In the configuration example shown in FIG. 14, the slit-shaped area ST is formed around the entire circumference of each of the sealing layers SE11, SE12, and SE13. Thus, in the formation of each of the display elements DE1, DE2, and DE3, an etching solution or an etching gas flows around the entire circumference of each of the display elements. This completely removes the stacked film on the partition 6.

This configuration example can achieve the same effect as in the above configuration examples.

In the embodiment, for example, the display element DE1 corresponds to the first embodiment, the display element DE2 corresponds to the second display element, and the display element DE3 corresponds to the third display element.

The sealing layer SE11 corresponds to the first sealing layer, the sealing layer SE12 corresponds to the second sealing layer, and the sealing layer SE13 corresponds to the third sealing layer.

The lower electrode LE1 corresponds to the first lower electrode, the lower electrode LE2 corresponds to the second lower electrode, and the lower electrode LE3 corresponds to the third lower electrode.

The organic layer OR1 corresponds to the first organic layer, the organic layer OR2 corresponds to the second organic layer, the organic layer OR3 corresponds to the third organic layer, the light emitting layer EM1 corresponds to the first light emitting layer, the light emitting layer EM2 corresponds to the second light emitting layer, and the light emitting layer EM3 corresponds to the third light emitting layer.

The upper electrode UE1 corresponds to the first upper electrode, the upper electrode UE2 corresponds to the second upper electrode, and the third upper electrode UE3 corresponds to the third upper electrode.

The cap layer CP1 corresponds to the first cap layer, the cap layer CP2 corresponds to the second cap layer, and the cap layer CP3 corresponds to the third cap layer.

The stacked film FL1 corresponds to the first stacked film, the stacked film FL2 corresponds to the second stacked film, and the stacked film FL3 corresponds to the third stacked film.

As described above, the present embodiment can provide a display device capable of improving the display quality and a manufacturing method of the display device.

All of the display devices and manufacturing methods thereof that can be implemented by a person of ordinary skill in the art through arbitrary design changes to the display device and manufacturing method thereof disclosed above as each embodiment of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or by adding or omitting a step or changing the condition of a step, all of the modifications fall within the scope of the present invention as long as they are in keeping with the spirit of the invention.

Further, other effects which may be obtained from the above embodiments and are self-explanatory from the descriptions of the specification or can be arbitrarily conceived by a person of ordinary skill in the art are considered as the effects of the present invention as a matter of course.

What is claimed is

1. A display device comprising:
a substrate;
an inorganic insulating layer provided above the substrate;
a first display element configured to display a first color;
a second display element configured to display a second color different from the first color;
a third display element configured to display a third color different from the first color and the second color;
a partition provided on the inorganic insulating layer, having conductivity, surrounding each of the first display element, the second display element, and the third display element, and formed in an overhang shape;
a first sealing layer covering the first display element and extending above the partition;
a second sealing layer covering the second display element and extending above the partition; and
a third sealing layer covering the third display element and extending above the partition, wherein
a distance between the second sealing layer and the third sealing layer is greater than a distance between the first sealing layer and the third sealing layer, and
a reflective layer is not provided between the partition and the first sealing layer, between the partition and the second sealing layer, and the partition and the third sealing layer.

2. The display device of claim 1, wherein
the distance between the second sealing layer and the third sealing layer is 10 times or more the distance between the first sealing layer and the third sealing layer.

3. The display device of claim 2, wherein
the distance between the second sealing layer and the third sealing layer is 5 μm or more.

4. The display device of claim 2, wherein
the distance between the first sealing layer and the third sealing layer is 0.5 μm or less.

5. A display device comprising:
a substrate;
an inorganic insulating layer provided above the substrate;
a partition provided on the inorganic insulating layer, having conductivity, and formed in an overhang shape; and
a plurality of pixels provided in a matrix in a first direction and a second direction, wherein
each of the plurality of pixels comprises:
a first display element configured to display a first color and surrounded by the partition;
a second display element configured to display a second color different from the first color and surrounded by the partition;
a third display element configured to display a third color different from the first color and the second color and surrounded by the partition;
a first sealing layer covering the first display element and extending above the partition;
a second sealing layer covering the second display element and extending above the partition; and
a third sealing layer covering the third display element and extending above the partition,
the third sealing layer is located between two of the first sealing layers in the first direction,
a distance between the third sealing layer and one of the first sealing layers in the first direction is greater than a distance between the third sealing layer and the other first sealing layer in the first direction, and
a reflective layer is not provided between the partition and the first sealing layer, between the partition and the second sealing layer, and the partition and the third sealing layer.

6. The display device of claim 5, wherein
the third sealing layer is located between two of the second sealing layers in the second direction, and
a distance between the third sealing layer one of the second sealing layers in the second direction is greater than a distance between the third sealing layer and the other second sealing layer in the second direction.

7. The display device of claim 1, wherein
each of the first display element, the second display element, and the third display element includes an upper electrode formed of an alloy of magnesium and silver, and
the upper electrode is not provided on the provided on the partition.

8. The display device of claim 1, wherein
each of the first display element, the second display element, and the third display element includes:
a lower electrode having a peripheral portion covered with the inorganic insulating layer; and
a stacked film provided on the lower electrode and including an organic layer having a light emitting layer, an upper electrode, and a cap layer, and
the stacked film is not provided on the partition.

9. The display device of claim 1, further comprising:
a resin layer covering the first sealing layer, the second sealing layer, and the third sealing layer, and
the resin layer fills respective cavities formed between the partition and the first sealing layer, between the partition and the second sealing layer, and the partition and the third sealing layer.

10. The display device of claim 7, wherein
the partition comprises:
a lower portion provided on the inorganic insulating layer, formed of a conductive material, and contacting the upper electrode; and
an upper portion provided on the lower portion.

11. The display device of claim 10, wherein
the lower portion comprises a bottom layer provided on the inorganic insulating layer and a stem layer provided between the bottom layer and the upper portion, and
both end portions of the bottom layer and both end portions of the upper portion protrude relative to side surfaces of the stem layer.

12. The display device of claim 1, wherein the third color is red.

13. A manufacturing method of a display device, the method comprising:
providing a processing substrate comprising a first lower electrode, a second lower electrode, a third lower electrode, and a partition above a substrate, the partition having an overhang shape and surrounding each of the first lower electrode, the second lower electrode, and the third lower electrode;
forming a first stacked film on the first lower electrode, the first stacked film including the first organic layer, the first upper electrode, and the first cap layer;
forming a first sealing layer on the first stacked film;
forming a second stacked film on the second lower electrode, the second stacked film including the second organic layer, the second upper electrode, and the second cap layer;
forming a second sealing layer on the second stacked film;
forming a third stacked film on the first sealing layer, the second sealing layer, the partition, and the third lower electrode, the third stacked film including the third organic layer, the third upper electrode, and the third cap layer;
forming a third sealing layer on the third stacked film;
forming a resist patterned into a predetermined shape on the third sealing layer; and
patterning the third sealing layer and the third stacked film using the resist as a mask, wherein
the resist is formed such that a distance from the resist to an edge portion of the second sealing layer is greater than a distance from the resist to an edge portion of the first sealing layer.

14. The manufacturing method of claim 13, further comprising:
removing the resist after patterning the third sealing layer and the third stacked film, wherein
the third stacked film on the partition is removed in the step of removing the resist.

15. The manufacturing method of claim 14, further comprising:
forming a resin layer on the first sealing layer, the second sealing layer, and the third sealing layer after removing the resist, wherein
the resin layer fills respective cavities formed between the partition and the first sealing layer, between the partition and the second sealing layer, and the partition and the third sealing layer.

16. The manufacturing method of claim 14, wherein
each of the first upper electrode, the second upper electrode, and the third upper electrode is formed of an alloy of magnesium and silver and does not exist on the partition after removing the resist.

17. The manufacturing method of claim 13, wherein
each of the first stacked film, the second stacked film, and the third stacked film is formed by vapor deposition using the partition as a mask.

18. The manufacturing method of claim 17, wherein
the third stacked film is divided into a portion formed on the partition and a portion formed on the third lower electrode.

19. The manufacturing method of claim 13, wherein
respective light-emitting layers included in the first organic layer, the second organic layer, and the third organic layer are formed of materials different from each other.

20. The manufacturing method of claim 13, wherein
the light emitting layer included in the third organic layer is formed of a material that emits light in red wavelength range.
